(19) United States
(12) Patent Application Publication
(10) Pub. No.: US 2017/0192323 A1
(43) Pub. Date: Jul. 6, 2017

(54) STORAGE CAPACITOR, PIXEL UNIT AND METHOD FOR MANUFACTURING STORAGE CAPACITOR

(71) Applicant: SHENZHEN CHINA STAR OPTOELECTRONICS TECHNOLOGY CO., LTD, Guangdong (CN)

(72) Inventors: Xiaohui YAO, Shenzhen, Guangdong (CN); Je Hao HSU, Shenzhen, Guangdong (CN)

(21) Appl. No.: 14/782,188

(22) PCT Filed: Jan. 22, 2015
(86) PCT No.: PCT/CN2015/071294

§ 371 Date: Feb. 1, 2016

(30) Foreign Application Priority Data
Jan. 23, 2014 (CN) 201410033377.7

(51) Int. Cl. G02F 1/1362; H01L 27/12; G02F 1/1368; G02F 1/1333; G02F 1/1343

(52) U.S. Cl. CPC G02F 1/136213; G02F 1/133345; G02F 1/134309; G02F 1/13439; G02F 1/136286; G02F 1/1368; H01L 27/1255; H01L 27/124; G02F 2001/133302; G02F 2201/123; G02F 2201/40

(57) ABSTRACT

The present invention discloses a storage capacitor. The storage capacitor includes a substrate, a first electrode formed on the substrate and changed from a first metal layer, a first insulating layer formed on the the substrate and the first electrode, a semiconductor layer formed on the first insulating layer, a second metal layer formed on the semiconductor layer, a second insulating layer formed on the first insulating layer, the semiconductor layer, and the second metal layer, and a pixel electrode formed on the second insulating layer and the second metal layer. The second insulating layer defines a contact window to expose the second metal layer. The pixel electrode contacts the second metal layer via the contact window.

### FIELD OF THE INVENTION

The present invention relates to semiconductor manufacturing technologies, and particularly, to a storage capacitor, a pixel unit, and a method for manufacturing the storage capacitor.

### BACKGROUND OF THE INVENTION

A thin film transistor (TFT) array is a key component of the liquid crystal display (LCD). The TFT array is composed of a number of pixel units, a number of scan lines, and a number of data lines. The pixel units are electrically connected to the scan lines and the data lines. Each of the pixel units has a thin film transistor, a liquid crystal capacitor (CLC), and a storage capacitor (CS). The CLC is charged to drive the liquid crystal molecules within the liquid crystal layer to display an image in the LCD panel. Meanwhile, the storage capacitors connected to the data lines are charged. The charged storage capacitors are used to maintain the voltage potential to be constant in both terminals of the CLC. That is, the voltage potentials in both terminals are kept to be constant by the charged storage capacitors before the data of the data lines are updated.

Currently, the storage capacitor includes a first metal layer/an insulating layer/a second metal layer (Metal-Insulator-Metal, MIM) structure and a first metal layer/an insulating layer/an indium tin oxide (Metal-Insulator-ITO, MII) structure. Because a semiconductor layer is under the second metal layer electrically connected to the TFT, the capacitance of the storage capacitor of the MIM structure will be changed when in an exchange between positive and negative. Unstable storage capacitor will make the display properties of the LCD panel instability. In addition, because the semiconductor layer is wider than the second metal layer electrically connected to the TFT, the semiconductor layer will be exposed at the second metal layer and may release electrons, thereby also making the display properties of the LCD panel instability. The gap of the storage capacitor of the MII structure is generally large. Increasing the dimension of the storage capacitor can get a larger capacitance of the storage capacitor. However, this will decrease aperture ratio of the LCD panel.

Therefore, it is desired to provide a storage capacitor, a pixel unit, and a method for manufacturing the storage capacitor, which can overcome or at least alleviate the above-mentioned problem.

### SUMMARY OF THE INVENTION

To solve the above-mentioned problem, the present invention provides a storage capacitor. The storage capacitor includes a substrate, a first electrode formed on the substrate and changed from a first metal layer, a first insulating layer formed on the the substrate and the first electrode, a semiconductor layer formed on the first insulating layer, a second metal layer formed on the semiconductor layer, a second insulating layer formed on the first insulating layer, the semiconductor layer, and the second metal layer, and a pixel electrode formed on the second insulating layer and the second metal layer. The second insulating layer defines a contact window to expose the second metal layer. The pixel electrode contacts the second metal layer via the contact window.

Wherein, the substrate is made of glass or plastic.

Wherein, the first electrode is a Mo layer, an aluminum layer, a titanium layer, a copper layer, or two layers stacked one on another selected from the Mo layer, the aluminum layer, the titanium layer, and the copper layer.

Wherein, the first electrode is a common line.

Wherein, the first electrode is a scan line.

Wherein, the first insulating layer is a SiNx layer, and the second insulating layer is a silicon oxide layer or a silicon nitride layer.

Wherein, the pixel electrode is a transparent conductive layer and is made of indium tin oxide.

To solve the above-mentioned problem, the present invention provides a pixel unit. The pixel unit includes a storage capacitor and a thin film transistor. The storage capacitor includes a substrate, a first electrode formed on the substrate and changed from a first metal layer, a first insulating layer formed on the the substrate and the first electrode, a semiconductor layer formed on the first insulating layer, a second metal layer formed on the semiconductor layer, a second insulating layer formed on the first insulating layer, the semiconductor layer, and the second metal layer, and a pixel electrode formed on the second insulating layer and the second metal layer. The pixel electrode serves as a second electrode. The second insulating layer defines a contact window to expose the second metal layer. The pixel electrode contacts the second metal layer via the contact window. The thin film transistor is electrically connected to the pixel electrode.

Wherein, the substrate is made of glass or plastic.

Wherein, the first electrode is a Mo layer, an aluminum layer, a titanium layer, a copper layer, or two layers stacked one on another selected from the Mo layer, the aluminum layer, the titanium layer, and the copper layer.

Wherein, the first electrode is a common line.

Wherein, the first electrode is a scan line.

Wherein, the first insulating layer is a SiNx layer, and the second insulating layer is a silicon oxide layer or a silicon nitride layer.

Wherein, the pixel electrode is a transparent conductive layer and is made of indium tin oxide.

To solve the above-mentioned problem, the present invention provides a method for manufacturing a storage capacitor. The method includes: providing a substrate; forming a first metal layer on the substrate and patterning the metal layer to form a first electrode; forming a first insulating layer on the substrate and the first electrode; forming a semiconductor layer and a second metal layer on the first insulating layer in sequence; forming a second insulating layer on the first insulating layer, the semiconductor layer, and the second metal layer, and exposing a portion of the second metal layer at a contact window; and forming a pixel electrode on the second insulating layer and on the portion of the second metal layer exposed at the contact window.

In the storage capacitor, the method for manufacturing the storage capacitor, and the pixel unit, the second metal layer merely adjusts a capacitance. The second insulting layer, which is instead of the MIM structure, is positioned under the pixel electrode severed as a second electrode. Thus, the capacitance of the storage capacitor remains stable when in an exchange between positive and negative, and releasing electrons of the semiconductor is avoided. Therefore, the display properties of the LCD panel can be assured. In addition, the contact window reduces the gap of the storage capacitor. Because the capacitance is inversely proportional to the distance, the area of the storage capacitor is less than that of the storage capacitor of the MII structure under the same capacitance. Thus, the aperture ratio of the LCD panel having the storage capacitor is larger than the LCD panel having the MII structure.

### BRIEF DESCRIPTION OF THE DRAWINGS

In order to illustrate technical schemes of the present invention or the prior art more clearly, the following section briefly introduces drawings used to describe the embodiments and prior art. Obviously, the drawing in the following descriptions just is some embodiments of the present invention. The ordinary person in the related art can acquire the other drawings according to these drawings without offering creative effort.

FIGS. 1-6 are schematic views showing a method for manufacturing a storage capacitor in accordance with a first exemplary embodiment of the present invention.

FIG. 7 is a schematic view of a pixel unit in accordance with a second exemplary embodiment.

### DETAILED DESCRIPTION OF THE PREFERRED EMBODIMENTS

The following sections offer a clear, complete description of the present invention in combination with the embodiments and accompanying drawings. Obviously, the embodiments described herein are only a part of, but not all of the embodiments of the present invention. In view of the embodiments described herein, any other embodiment obtained by the person skilled in the field without offering creative effort is included in a scope claimed by the present invention.

### The First Embodiment

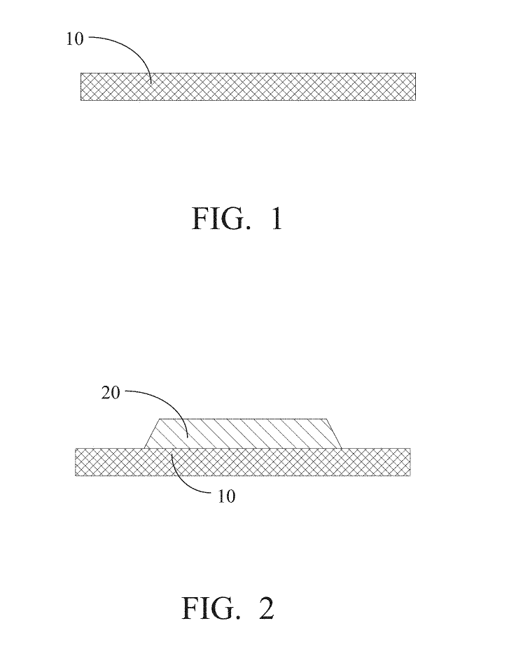

Referring to FIGS. 1-6, a method for manufacturing a storage capacitor, in accordance with a first embodiment, includes the following steps.

First, referring to FIG. 1, a substrate is provided 10. The substrate 10 can be made of glass or plastic. In this embodiment, the substrate 10 is made of glass.

Second, referring to FIG. 2, a first metal layer is formed on the substrate 10, and a first electrode 20 is formed via patterning the first metal layer. In this embodiment, the first metal layer can be a Mo layer, an aluminum layer, a titanium layer, a copper layer, or two layers stacked one on another selected from the Mo layer, the aluminum layer, the titanium layer, and the copper layer. The first metal layer is formed on the substrate 10 via a sputtering process, and a yellow-light photolithography process is applied in the step of patterning the first metal layer to form the first electrode 20.

The yellow-light photolithography process includes an exposure process, a development process, and an etching process. In detail, first, a photo-resistance layer is formed on the first metal. Second, the photo-resistance layer is exposed using a gray tone mask or a half tone mask. The pattern of the gray tone mask or the half tone mask corresponds to the pattern of the first electrode 20. The pattern of the gray tone mask or the half tone mask is transferred to the photo-resistance layer. Third, part of the photo-resistance layer is removed using a developer, thereby a required pattern corresponding to the first electrode 20 is formed on the rest of the photo-resistance layer. Fourth, part of the first metal layer uncovered by the rest of the photo-resistance layer is removed via an etching process. The etching process can be a dry-etching process, a wet-etching process, or a combination of the dry-etching process and the wet-etching process. Fifth, the rest of the photo-resistance layer is removed, thereby forming the first electrode 20 having predetermined pattern.

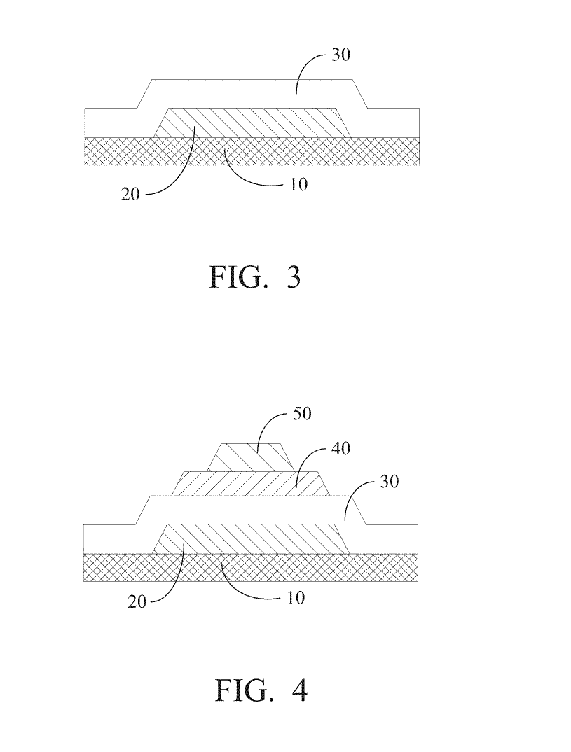

Third, referring to FIG. 3, a first insulating layer 30 is formed on the substrate 10 and the first electrode 20. The first insulating layer 30 is a SiNx layer, and is formed on the substrate 10 and the first electrode 20 via a chemical vapor deposition (CVD) process.

Fourth, referring to FIG. 4, a semiconductor layer 40 and a second metal layer 50 are formed on the first insulating layer 30 in sequence. This step is achieved via a yellow-light photolithography process which is the same as the yellow-light photolithography process of the second step.

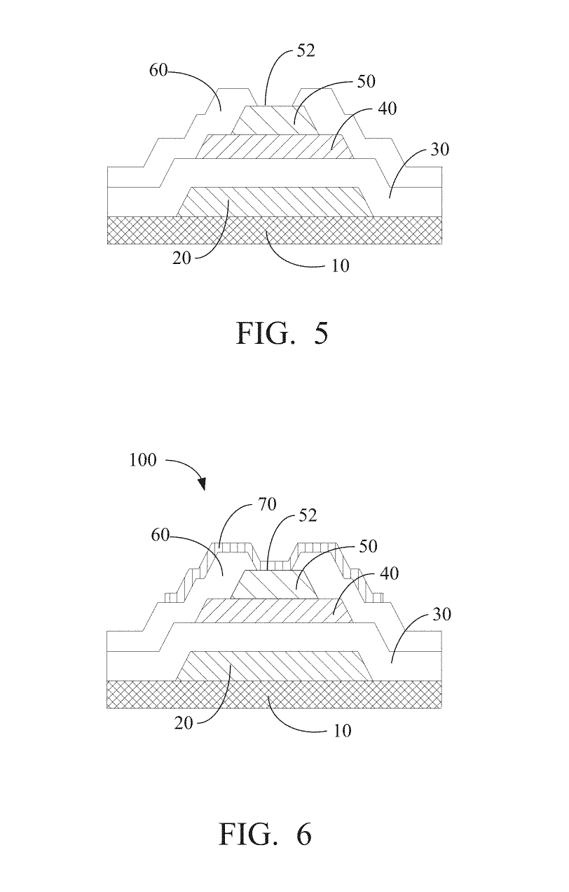

Fifth, referring to FIG. 5, a second insulating layer 60 is formed on the first insulating layer 30, the semiconductor layer 40, and the second metal layer 50, and a portion of the second metal layer 50 is exposed at a contact window 52. In detail, a silicon oxide layer or a silicon nitride layer is deposited on the first insulating layer 30, the semiconductor layer 40, and the second metal layer 50 using a CVD process, and then the second insulating layer 60 using a yellow-light photolithography process.

Sixth, referring to FIG. 6, a pixel electrode 70 is formed on the second insulating layer 60 and the exposure second metal layer 50. The pixel electrode 70 electrically contacts the second metal layer 50. Thus, a storage capacitor 100 is formed. For one example, ITO is deposited on the second insulating layer 60 and the exposure second metal layer 50.

### The Second Embodiment

Referring to FIG. 6, a storage capacitor 100, in accordance with a second embodiment, includes a substrate 10, a first electrode 20, a first insulating layer 30, a semiconductor layer 40, a second metal layer 50, a second insulating layer 60, and a pixel electrode 70. The first electrode 20 is positioned on the substrate 10 and is changed from a first metal layer. The first insulating layer 30 is formed on the substrate 10 and the first electrode 20. The semiconductor layer 40 and the second metal layer 50 are formed on the first insulating layer 30 in sequence. The second insulating layer 60 is formed on the first insulating layer 30, the semiconductor layer 40, and the second metal layer 50. The pixel electrode 70 is formed on the second insulating layer 60 and the second metal layer 50.

The substrate 10 can be made of glass or plastic. In this embodiment, the substrate 10 is made of glass. The first electrode 20 can be a Mo layer, an aluminum layer, a titanium layer, a copper layer, or two layers stacked one on another selected from the Mo layer, the aluminum layer, the titanium layer, and the copper layer. The first insulating layer 30 is a SiNx layer. The second insulating layer 60 is a silicon oxide layer or a silicon nitride layer. The second insulating layer 60 defines a contact window 52 to expose the second metal layer 50. The pixel electrode 70 electrically contacts the second metal layer 50 at the contact window 52. The pixel electrode 70 is a transparent conductive layer and is made of ITO.

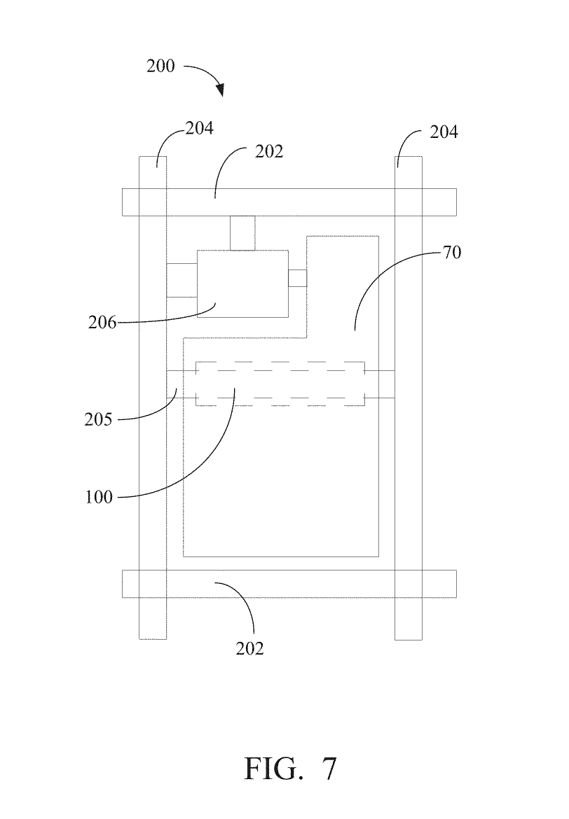

Referring to FIG. 7, in this embodiment, the first electrode 20 can be a common line 205. In other embodiments, the first electrode 20 can be a scan line 202.

### The Third Embodiment

Referring to FIG. 7, a pixel unit 200, in accordance with a third embodiment, is defined by two neighboring scan lines 202 and two neighboring data lines 204. The pixel unit 200 includes a TFT 206 and a storage capacitor 100 of the first embodiment. The gate electrode of the TFT 206 is electrically connected to the scan line 202. The source electrode of the TFT 206 is electrically connected to the data line 204. The drain electrode of the TFT 206 is electrically connected to the pixel electrode 70 of the storage capacitor 100. The scan line 202 provides a scan voltage for the TFT 206 to make the TFT 206 breakover. The data line 204 provides a data voltage for the TFT 206 to make the gray tone of the pixel electrode 70 correspond to the data voltage. The storage capacitor 100 is configured to store a display voltage of the pixel electrode 70 when the TFT 206 is shut off. That is, the voltage of the pixel electrode 70 is kept to be constant by the storage capacitor 100 before the data of the data lines 204 are updated.

In the storage capacitor 100, the method for manufacturing the storage capacitor 100, and the pixel unit 200, the second metal layer 50 merely adjusts a capacitance. The second insulting layer 60, which is instead of the MIM structure, is positioned under the pixel electrode 70 severed as a second electrode. Thus, the capacitance of the storage capacitor 100 remains stable when in an exchange between positive and negative, and releasing electrons of the semiconductor 40 is avoided. Therefore, the display properties of the LCD panel can be assured. In addition, the contact window 52 reduces the gap of the storage capacitor 100. Because the capacitance is inversely proportional to the distance, the area of the storage capacitor 100 is less than that of the storage capacitor of the MII structure under the same capacitance. Thus, the aperture ratio of the LCD panel having the storage capacitor 100 is larger than the LCD panel having the MII structure.

What is said above are only preferred examples of present invention, not intended to limit the present invention, any modifications, equivalent substitutions and improvements etc. made within the spirit and principle of the present invention, should be included in the protection range of the present invention.

What is claimed is:

1. A storage capacitor, comprising a substrate, a first electrode formed on the substrate and changed from a first metal layer, a first insulating layer formed on the the substrate and the first electrode, a semiconductor layer formed on the first insulating layer, a second metal layer formed on the semiconductor layer, a second insulating layer formed on the first insulating layer, the semiconductor layer, and the second metal layer, and a pixel electrode formed on the second insulating layer and the second metal layer, the second insulating layer defining a contact window to expose the second metal layer, and the pixel electrode contacting the second metal layer via the contact window.

2. The storage capacitor of claim 1, wherein the substrate is made of glass or plastic.

3. The storage capacitor of claim 1, wherein the first electrode is a Mo layer, an aluminum layer, a titanium layer, a copper layer, or two layers stacked one on another selected from the Mo layer, the aluminum layer, the titanium layer, and the copper layer.

4. The storage capacitor of claim 1, wherein the first electrode is a common line.

5. The storage capacitor of claim 1, wherein the first electrode is a scan line.

6. The storage capacitor of claim 1, wherein the first insulating layer is a SiNx layer, and the second insulating layer is a silicon oxide layer or a silicon nitride layer.

7. The storage capacitor of claim 1, wherein the pixel electrode is a transparent conductive layer and is made of indium tin oxide.

8. A pixel unit, comprising a storage capacitor and a thin film transistor, the storage capacitor comprising a substrate, a first electrode formed on the substrate and changed from a first metal layer, a first insulating layer formed on the the substrate and the first electrode, a semiconductor layer formed on the first insulating layer, a second metal layer formed on the semiconductor layer, a second insulating layer formed on the first insulating layer, the semiconductor layer, and the second metal layer, and a pixel electrode formed on the second insulating layer and the second metal layer, the pixel electrode serving as a second electrode, the second insulating layer defining a contact window to expose the second metal layer, the pixel electrode contacting the second metal layer via the contact window, and the thin film transistor electrically connected to the pixel electrode.

9. The pixel unit of claim 8, wherein the substrate is made of glass or plastic.

10. The pixel unit of claim 8, wherein the first electrode is a Mo layer, an aluminum layer, a titanium layer, a copper layer, or two layers stacked one on another selected from the Mo layer, the aluminum layer, the titanium layer, and the copper layer.

11. The pixel unit of claim 8, wherein the first electrode is a common line.

12. The pixel unit of claim 8, wherein the first electrode is a scan line.

13. The pixel unit of claim 8, wherein the first insulating layer is a SiNx layer, and the second insulating layer is a silicon oxide layer or a silicon nitride layer.

14. The pixel unit of claim 8, wherein the pixel electrode is a transparent conductive layer and is made of indium tin oxide.

15. A method for manufacturing a storage capacitor, comprising:
providing a substrate;
forming a first metal layer on the substrate and patterning the metal layer to form a first electrode;
forming a first insulating layer on the substrate and the first electrode;
forming a semiconductor layer and a second metal layer on the first insulating layer in sequence;
forming a second insulating layer on the first insulating layer, the semiconductor layer, and the second metal layer, and exposing a portion of the second metal layer at a contact window; and
forming a pixel electrode on the second insulating layer and on the portion of the second metal layer exposed at the contact window.
